(19) United States
(12) Patent Application Publication
(10) Pub. No.: US 2014/0015388 A1
(43) Pub. Date: Jan. 16, 2014

(54) FLIPPABLE DOUBLE SIDED DESKTOP EASELS AND METHOD OF MANUFACTURE THEREOF

(71) Applicant: Asher DIAMANT, Holon (IL)

(72) Inventor: Asher DIAMANT, Holon (IL)

(21) Appl. No.: 13/545,159

(22) Filed: Jul. 10, 2012

(51) Int. Cl. A47B 97/04; H05K 5/03; A47B 96/00; B29C 45/14

(52) U.S. Cl. 312/230; 248/441.1; 264/242; 312/223.1; 312/326

(57) ABSTRACT

A flippable double-sided desktop easel which includes at least two interconnected double-sided easel panels, the panels being operable for interflipping therebetween, the interflipping being operable to alternatively expose alternating ones of sides of the panels, the interconnected double-sided easel panels being arranged for generally upright mounting on a horizontal surface.

### FIELD OF THE INVENTION

The present application relates to flippable double-sided desktop easels.

### BACKGROUND OF THE INVENTION

The following U.S. patents are believed to represent the current state of the art:

U.S. Pat. Nos. 4,552,362; 5,454,745; 6,626,675; 7,967,694; 7,972,219 and 7,972,220.

### SUMMARY OF THE INVENTION

The present invention seeks to provide a flippable double-sided desktop easel.

There is thus provided in accordance with a preferred embodiment of the present invention a flippable double-sided desktop easel including at least two interconnected double-sided easel panels, the panels being operable for interflipping therebetween, the interflipping being operable to alternatively expose alternating ones of sides of the panels, the interconnected double-sided easel panels being arranged for generally upright mounting on a horizontal surface.

In accordance with a preferred embodiment of the present invention, a main portion of the easel is formed in a double-sided mold by injection molding. Preferably, the mold includes a base portion and an ejector mold, the base portion including a base plate having at least two tracks and an injection mold, corresponding to the ejector mold, mounted thereupon. Preferably, at least one slidable molding insert element is slidably mounted on the tracks on opposite ends of the injection mold, each of the at least one insert element including at least one mold place-holder.

Preferably, slidable movement of the at least one slidable molding insert element relative to the injection mold is controlled by at least one piston which connects between the at least one slidable molding insert element and the injection mold. Preferably, prior to the injection molding of the main portion, the at least one piston is employed to slidably engage the at least one slidable molding insert element with the injection mold, thereby inserting the at least one mold place-holder into the interior of the injection mold. Additionally, subsequent to the injection molding of the main portion, the at least one piston is employed to slidably disengage the at least one slidable molding insert element from the injection mold, thereby exposing at least one recess integrally formed in the periphery of the main portion by the mold place-holders.

Preferably, the main portion includes a first easel panel frame interconnected to a second easel panel frame by integrally formed flexible connectors. Preferably, at least one of the first and second frames includes an integrally formed double-sided easel panel. Preferably, a snap-fit double-sided easel panel is snap fitted into one of the first and second frames. Preferably, the snap-fit double-sided easel panel includes electronic drawing functionality.

Preferably, at least one of the first and second frames includes a compartment having a hinged door, the compartment being operable for storing at least one of electronic components of the electronic drawing functionality and drawing tools. Preferably, the hinged door is also operative to serve as a tray for placing the drawing tools while using the easel. Preferably, two top covers are each snap-fitted into a top portion of each of the frames, and leg elements are snap fitted into the at least one recess.

Preferably, adjustable locking elements are provided for interconnecting knobs formed on the periphery of each of the frames, the knobs being operable for locking the frames in one of a generally upright position and a mutually perpendicular arrangement. Preferably, the top covers, the leg elements and the locking elements are formed by injection molding. Preferably, each side of the double-sided easel panels includes at least one of a magnetic board, a chalkboard, a drawing board, and a rub-on coloring board.

Preferably, when in the generally upright position, at least one side of each of the double-sided easel panels is accessible. Preferably, the interflipping includes detaching the locking elements from the knobs, flipping one of the frames above and over another one of the frames and reattaching the locking elements to the knobs.

There is also provided in accordance with another preferred embodiment of the present invention a method of manufacturing a flippable double-sided desktop easel including forming. by injection molding, at least two interconnected double-sided easel panels, the panels being operable for interflipping therebetween, the interflipping being operable to alternatively expose alternating ones of sides of the panels, the interconnected double-sided easel panels being arranged for generally upright mounting on a horizontal surface.

In accordance with a preferred embodiment of the present invention, a main portion of the easel is formed in a double-sided mold. Preferably, the mold includes a base portion and an ejector mold, the base portion including a base plate having at least two tracks and an injection mold, corresponding to the ejector mold, mounted thereupon. Preferably, at least one slidable molding insert element is slidably mounted on the tracks on opposite ends of the injection mold, each of the at least one insert element including at least one mold place-holder.

Preferably, slidable movement of the at least one slidable molding insert element relative to the injection mold is controlled by at least one piston which connects between the at least one slidable molding insert element and the injection mold. Preferably, the method also includes, prior to the injection molding of the main portion, employing the at least one piston to slidably engage the at least one slidable molding insert element with the injection mold, thereby inserting the at least one mold place-holder into the interior of the injection mold.

Preferably, the method also includes, subsequent to the injection molding of the main portion, employing the at least one piston to slidably disengage the at least one slidable molding insert element from the injection mold, thereby exposing at least one recess integrally formed in the periphery of the main portion by the mold place-holders. Preferably, the method also includes integrally forming at least one flexible connector which interconnects between a first easel panel frame of the easel and a second easel panel frame of the easel.

Preferably, the method also includes integrally forming a double-sided easel panel in at least one of the first and second frames. Preferably, the method also includes snap-fitting a snap-fit double-sided easel panel into one of the first and second frames. Preferably, the snap-fit double-sided easel panel includes electronic drawing functionality.

Preferably, the method also includes forming, in at least one of the first and second frames, a compartment having a hinged door, the compartment being operable for storing at least one of electronic components of the electronic drawing functionality and drawing tools. Preferably, the hinged door is also operative to serve as a tray for placing the drawing tools while using the easel.

Preferably, the method also includes snap-fitting two top covers into a top portion of each of the frames, and snap-fitting leg elements into the at least one recess. Preferably, the method also includes providing adjustable locking elements for interconnecting knobs formed on the periphery of each of the frames, the knobs being operable for locking the frames in one of a generally upright position and a mutually perpendicular arrangement.

Preferably, the top covers, the leg elements and the locking elements are formed by injection molding. Preferably, each side of the at least one double-sided easel panel includes at least one of a magnetic board, a chalkboard, a drawing board, and a rub-on coloring board. Preferably, when in the generally upright position, at least one side of each of the double-sided easel panels is accessible. Preferably, the interflipping includes detaching the locking elements from the knobs, flipping one of the frames above and over another one of the frames and reattaching the locking elements to the knobs.

### BRIEF DESCRIPTION OF THE DRAWINGS

The present invention will be understood and appreciated more fully from the following detailed description, taken in conjunction with the drawings in which:

FIGS. 1A, 1B and 1C are simplified pictorial illustrations of one configuration of a flippable double-sided desktop easel constructed and operative in accordance with a preferred embodiment of the present invention;

FIG. 2 is a simplified pictorial illustration of steps in interflipping the flippable double-sided desktop easel of FIGS. 1A-1C;

FIGS. 3A and 3B are simplified pictorial illustrations of another configuration of the flippable double-sided desktop easel of FIGS. 1A-2;

FIGS. 4A and 4B are simplified pictorial illustrations of a process of molding a main portion of the flippable double-sided desktop easel of FIGS. 1A-3B;

FIG. 5 is a simplified pictorial illustration of a process of assembling the flippable double-sided desktop easel of FIGS. 4A and 4B; and

FIGS. 6A and 6B are simplified pictorial illustrations of alternate sides of the assembled flippable double-sided desktop easel of FIGS. 4A-5.

### DETAILED DESCRIPTION OF A PREFERRED EMBODIMENT

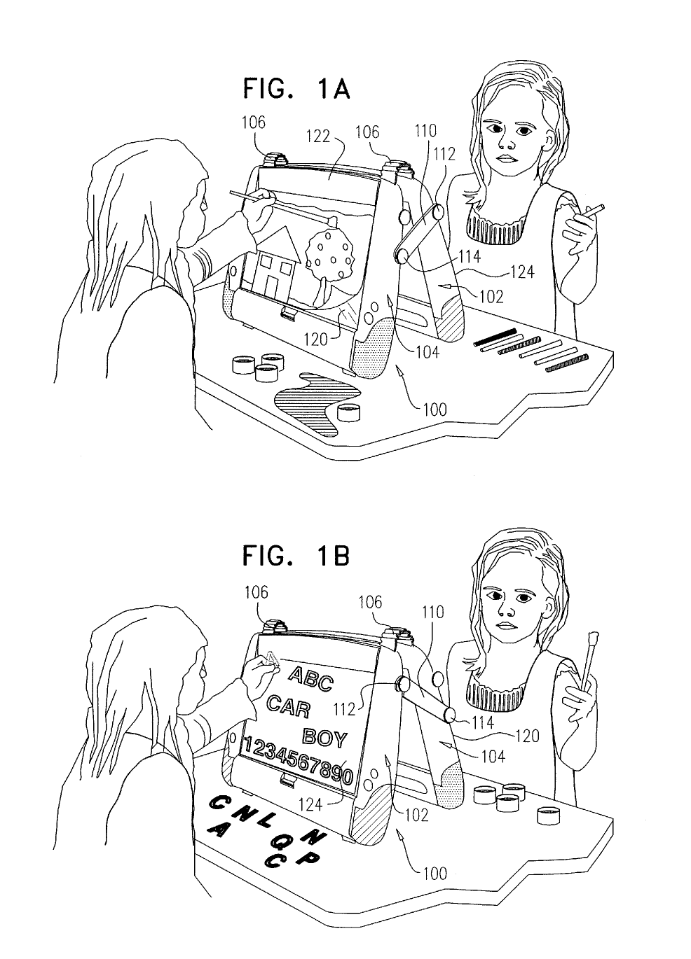

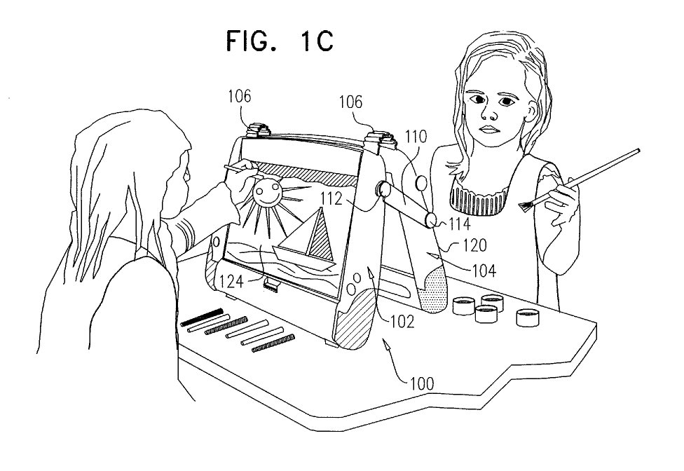

Reference is now made to FIGS. 1A, 1B and 1C, which are simplified pictorial illustrations of one configuration of a flippable double-sided desktop easel constructed and operative in accordance with a preferred embodiment of the present invention. The flippable double-sided desktop easel of FIGS. 1A-1C preferably includes at least two interconnected double-sided easel panels, the panels being operable for interflipping therebetween, the interflipping being operable to alternatively expose alternating ones of sides of the panels, the interconnected double-sided easel panels being arranged for generally upright mounting on a horizontal surface.

As shown in FIGS. 1A-1C, a flippable double-sided desktop easel 100 comprising two panel frames 102 and 104 interconnected by flexible connectors 106 is locked in a generally upright position, wherein locking elements 110 preferably interlock between knobs 112 and 114 of corresponding panel frames 102 and 104.

As shown in FIG. 1A, a first child employs a drawing board on side 120 of panel frame 104 to paint a picture on a sheet of paper which is inserted between side 120 of panel frame 104 and a corresponding top frame element 122. A second child simultaneously utilizes a magnetic chalkboard on side 124 of panel frame 102 for example, for drawing or writing in chalk.

Turning now to FIG. 1B it is shown that double-sided desktop easel 100 has been rotated so that the first child now has access to the magnetic chalkboard on side 124 of panel frame 102 while the second child now has access to the drawing board on side 120 of panel frame 104. As shown in FIG. 1B, the first child employs the magnetic chalkboard side 124 of panel frame 102 to magnetically fasten alpha-numeric characters thereto, while the second child employs the drawing board on side 120 of panel 104 for painting.

Alternatively, as shown in FIG. 1C, the first child utilizes the magnetic chalkboard on side 124 of panel frame 102 for drawing in chalk while the second child employs the drawing board on side 120 of panel frame 104 for painting.

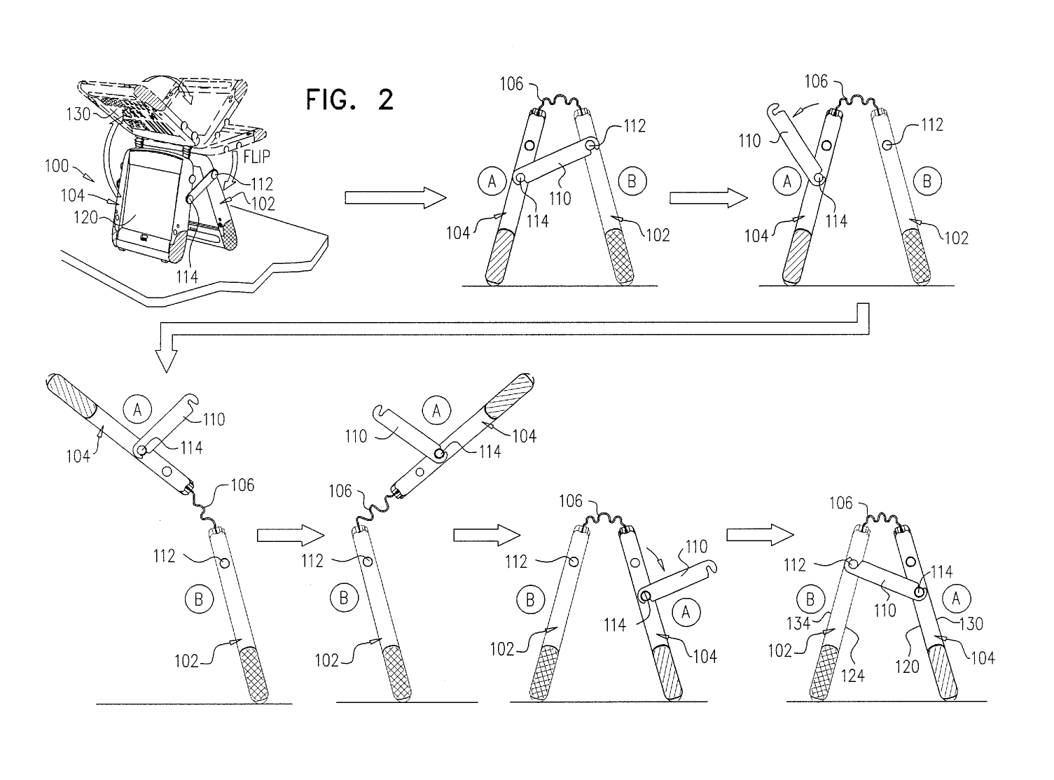

Reference is now made to FIG. 2, which is a simplified pictorial illustration of steps in interflipping the flippable double-sided desktop easel of FIGS. 1A-1C. As shown in FIG. 2, flippable double-sided desktop easel 100 is initially locked in a generally upright position, wherein locking elements 110 interlock between knobs 112 and 114 thereby interlocking corresponding panel frames 102 and 104, and wherein side 120 of panel frame 104 and side 124 of panel frame 102 are externally accessible. As described hereinabove, panel frames 102 and 104 are also interconnected by integrally formed flexible connectors 106.

As shown in FIG. 2, locking elements 110 may be detached from knob 112 of panel frame 102, thereby unlocking panel frame 102 from panel frame 104. As further shown in FIG. 2, panel frame 104 may be flipped above and over frame 102, and locking elements 110 may then be reattached to knob 112 of panel frame 102, thereby relocking panel frame 102 to panel frame 104, whereby side 130 of panel frame 104 and side 134 of panel frame 102 are now externally accessible.

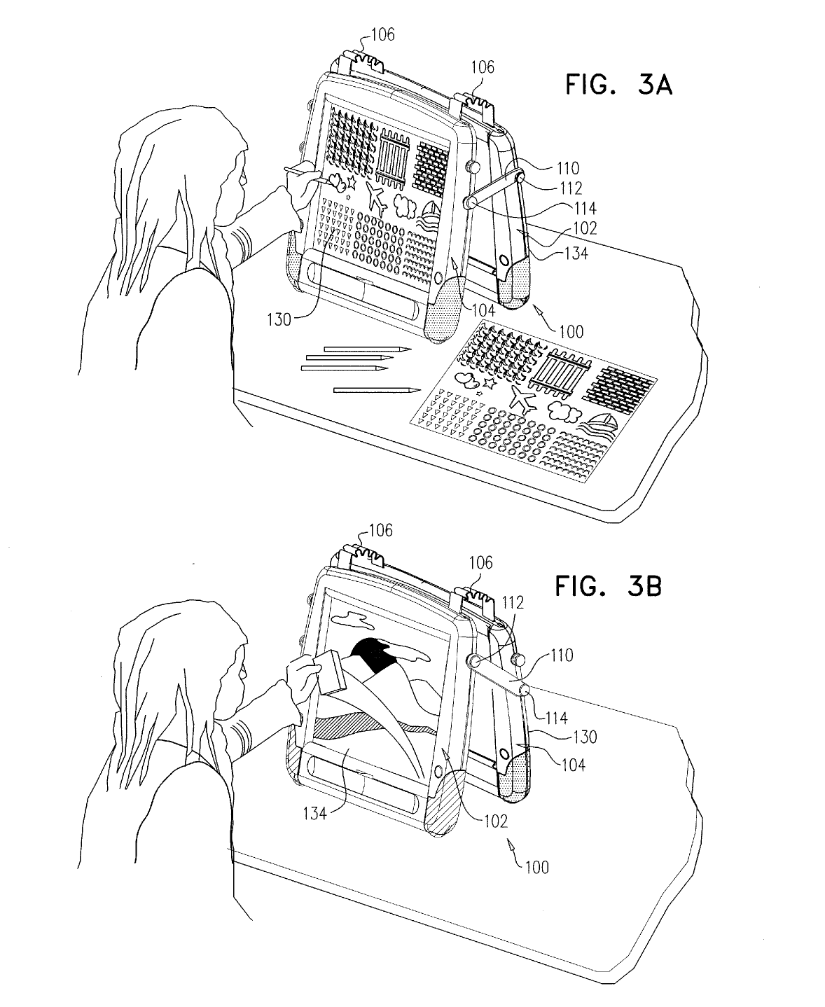

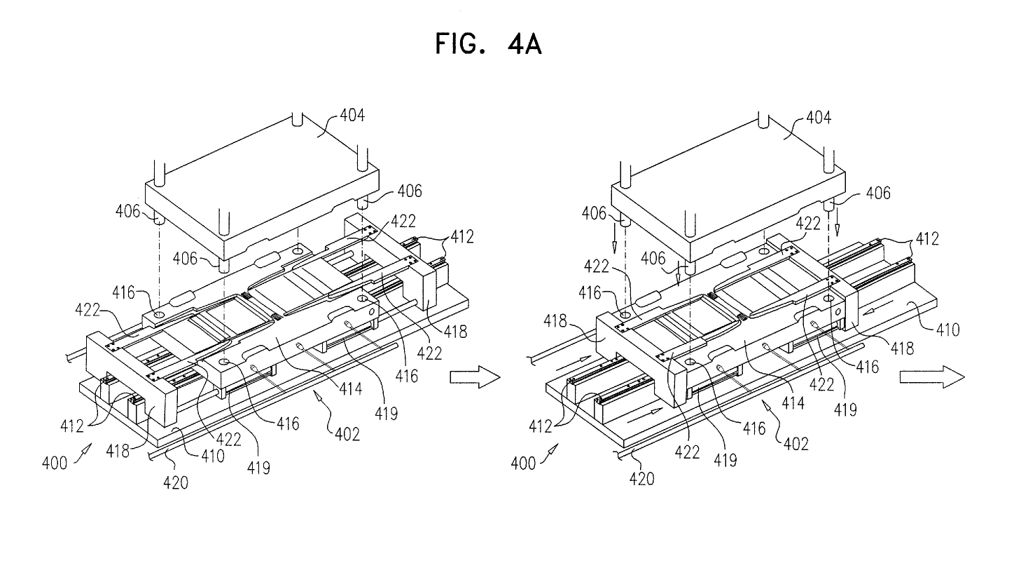

Reference is now made to FIGS. 3A and 3B, which are simplified pictorial illustrations of another configuration of the flippable double-sided desktop easel of FIGS. 1A-2. It is appreciated that the configuration of FIGS. 3A and 3B may be attained after interflipping flippable double-sided desktop easel 100 relative to the configuration of FIGS. 1A-2.

As shown in FIGS. 3A & 3B, flippable double-sided desktop easel 100 is locked in a generally upright position, wherein locking elements 110 interlock between knobs 112 and 114 of corresponding panel frames 102 and 104.

As shown particularly in FIG. 3A. a child employs the rub-on coloring board on side 130 of panel frame 104 to sketch a picture on a sheet of paper which is placed over side 130 of panel 104. As shown particularly in FIG. 3B, the double-sided desktop easel 100 has been rotated so that the child now has access to an electronic drawing board on side 134 of panel frame 102.

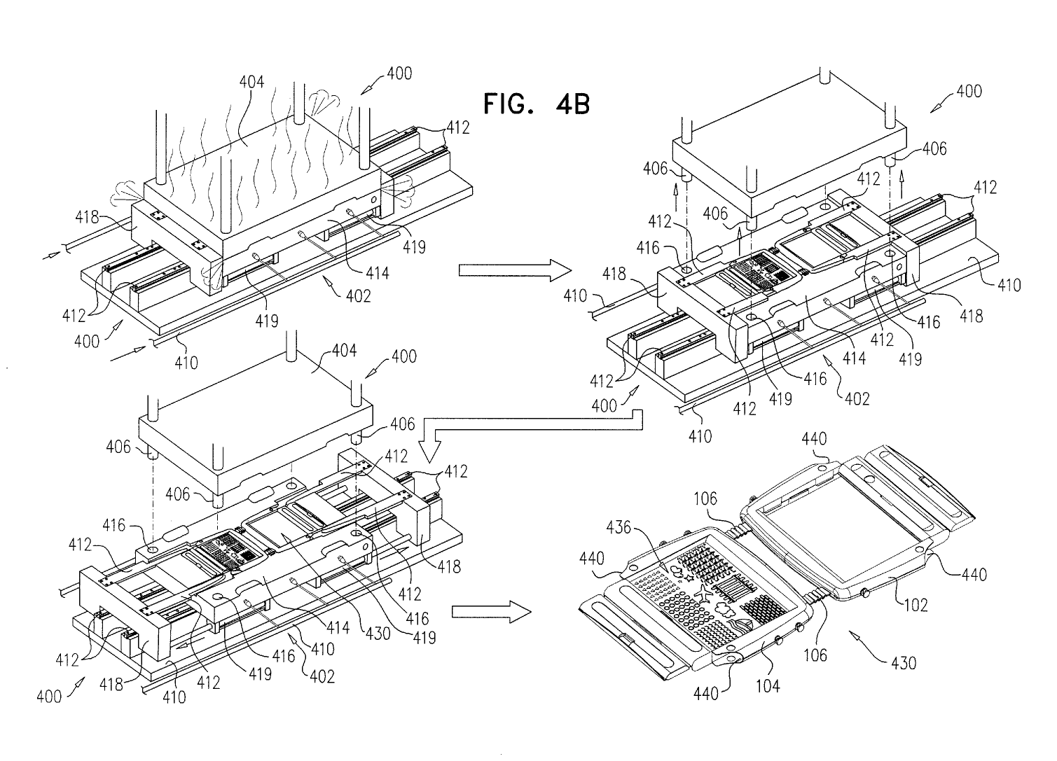

Reference is now made to FIGS. 4A and 4B, which are simplified pictorial illustrations of a process of molding a main portion of the flippable double-sided desktop easel of FIGS. 1A-3B. As shown in FIG. 4A, a double-sided mold 400 is provided for injection molding of a main portion of the flippable double-sided desktop easel. Mold 400 preferably includes a base portion 402 and an ejector mold 404 having four ejector pins 406 preferably integrally formed therewith.

Base portion 402 preferably includes a base plate 410 having two tracks 412 and an injection mold 414 mounted thereupon, injection mold 414 corresponding to ejector mold 404. Recesses 416 are preferably formed in injection mold 414 for receiving ejector pins 406. Two slidable molding insert elements 418 are slidably mounted on tracks 412 on opposite ends of injection mold 414. Slidable movement of elements 418 relative to injection mold 414 is preferably controlled by pistons 419 which connect elements 418 to injection mold 414. Sprues 420 are connected to injection mold 414 and provide access of molding material to the various areas of injection mold 414.

Each of slidable molding insert elements 418 preferably comprises two mold place-holders 422. As shown in FIG. 4A, before initiating the molding of the main portion of the flippable double-sided desktop easel, pistons 419 are employed to slidably engage molding insert elements 418 with injection mold 414, thereby inserting mold place-holders 422 into the interior of injection mold 414.

Turning now to FIG. 4B, it is shown that ejector mold 404 is engaged with injection mold 414 and molten molding material, such as polypropylene is injected via sprues 420 into injection mold 414. Subsequent to cooling and solidifying of the molding material, ejector mold 404 is disengaged from injection mold 414, thereby exposing a molded main portion 430 of the flippable double-sided desktop easel 100 of FIGS. 1A-3B. Main portion 430 preferably comprises first easel panel frame 102 which is interconnected to second easel panel frame 104 by integrally formed flexible connectors 106, which frame 104 preferably comprises an integrally formed easel panel 436.

Thereafter, pistons 419 are employed to slidably disengage slidable molding insert elements 418 from injection mold 414, thereby exposing two elongated recesses 440 formed in the periphery of each of panel frames 102 and 104 by mold place-holders 422. Main portion 430 may then be removed from injection mold 414.

It is a particular feature of the present invention that mold place-holders 422 are operative to facilitate forming of elongated recesses 440 in the periphery of each of panel frames 102 and 104, thereby facilitating forming of a partially hollow casting of panel frames 102 and 104 which is lightweight relative to its overall size.

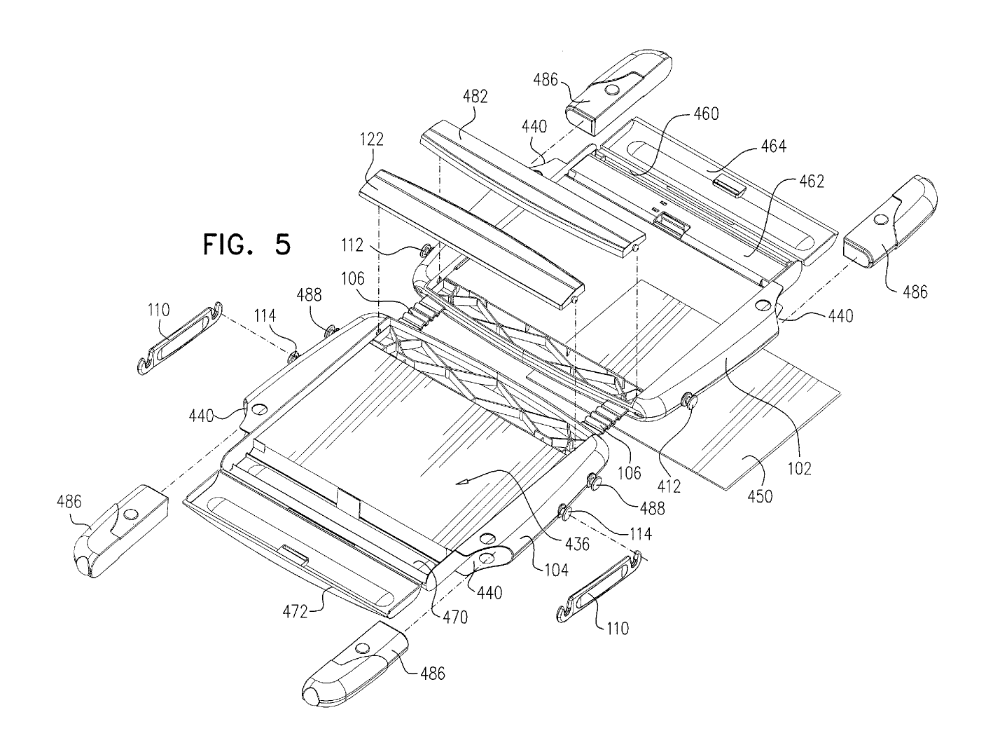

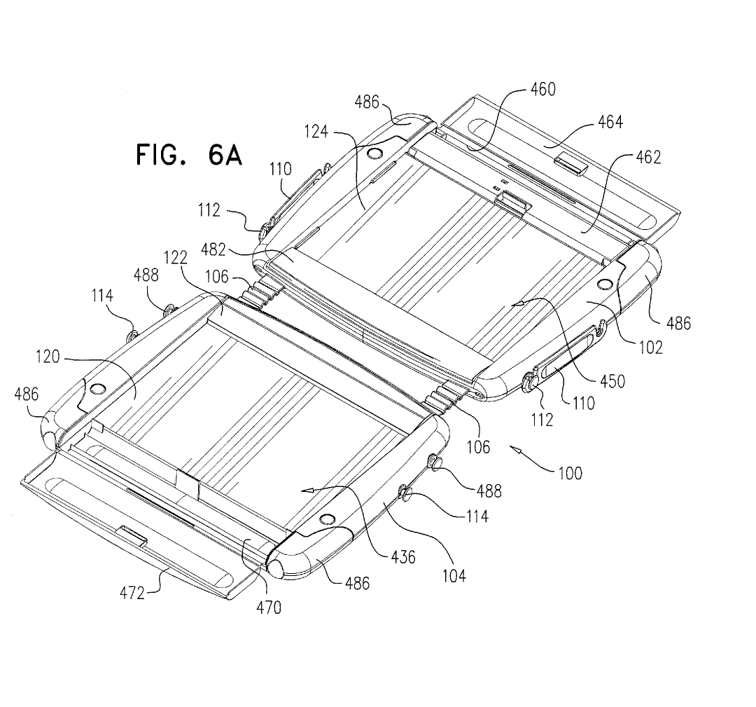

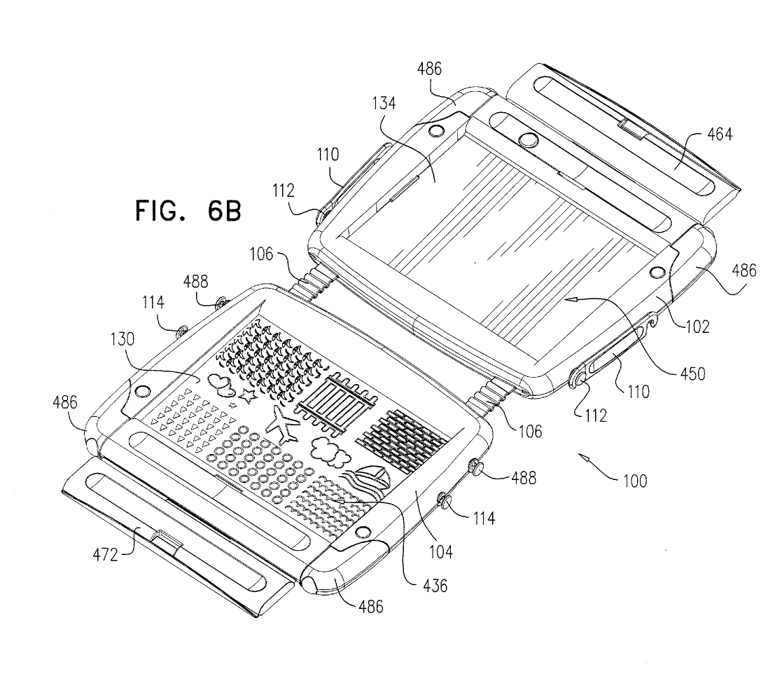

Reference is now made to FIG. 5, which is a simplified pictorial illustration of a process of assembling the flippable double-sided desktop easel of FIGS. 4A and 4B, and to FIGS. 6A and 6B. which are simplified pictorial illustrations of alternate sides of the assembled flippable double-sided desktop easel of FIGS. 4A-5.

As shown in FIG. 5, a double-sided easel panel 450 is preferably snap-fitted into panel frame 102. Panel 450 may, for example. comprise electronic functionality, such as, for example, an electronic drawing board or a back-lit drawing panel. Panel frame 102 preferably comprises a compartment 460 which houses electronic components (not shown) covered by a covering 462, which electronic components are preferably operable for operating panel 450. A hinged cover 464 is preferably provided for closing compartment 460.

Panel frame 104 preferably comprises a compartment 470 having a hinged cover 472 operable for closing compartment 470. It is appreciated that compartment 470 may be used to store accessories to be used with easel 100, such as, for example, drawings and painting tools. It is also appreciated that in the open configuration illustrated in FIG. 5, hinged covers 464 and 472 may also serve as a tray upon which the accessories may be placed for easy access.

Two top frame elements 482 and 122 are each preferably snap-fitted into a top portion of each of panel frames 102 and 104 respectively, and leg elements 486 are preferably snap fitted into elongated recesses 440 of each of panel frames 102 and 104. Adjustable locking elements 110 are preferably provided for interconnecting knobs 112 and 114 of corresponding panel frames 102 and 104 to lock panel frames 102 and 104 in a generally upright position, and for interconnecting between knobs 112 and 488 of corresponding panel frames 102 and 104 to lock panel frames 102 and 104 in a mutually perpendicular arrangement.

It is appreciated that top covers 122 and 482, leg elements 486 and locking elements 110 are preferably formed by an injection molding process which is separate from the injection molding process which forms main portion 430.

FIGS. 6A and 6B illustrate alternate sides of an assembled flippable double-sided desktop easel 100. As shown in FIGS. 6A and 6B and as described hereinabove with reference to FIG. 5, easel 100 comprises panel frames 102 and 104 of main portion 430, leg elements 486, adjustable locking elements 110, knobs 112, 114 and 488, compartments 460 and 470, and corresponding hinged covers 464 and 472.

As described hereinabove, double-sided easel panel 450 is preferably snap fitted into panel frame 102. As shown in FIG. 6A, a first side 124 of double-sided easel panel 450 preferably comprises a magnetic chalkboard which is operable for both chalk drawing thereupon and for fastening magnetic elements thereto. The magnetic elements may include, for example, magnetic alpha-numeric characters. As shown in FIG. 6B, a second side 134 of double-sided easel panel 450 preferably comprises an electronic drawing board.

Panel frame 104 preferably comprises a double-sided easel panel 436 integrally formed therewith. As shown in FIG. 6A, a first side 120 of panel 436 preferably comprises a drawing board to which sheets of drawing paper may be fastened by inserting the drawing paper between panel 136 and corresponding top frame element 122. As shown in FIG. 6B, a second side 130 of panel 104 preferably comprises a rub-on coloring board.

It will be appreciated by persons skilled in the art that the present invention is not limited by what has been particularly shown and described hereinabove. Rather the scope of the present invention includes both combinations and subcombinations of various features described hereinabove and variations and modifications thereof which would occur to persons skilled in the art upon reading the foregoing, which are not in the prior art.

1. A flippable double-sided desktop easel comprising:
at least two interconnected double-sided easel panels, said panels being operable for interflipping therebetween, said interflipping being operable to alternatively expose alternating ones of sides of said panels, said interconnected double-sided easel panels being arranged for generally upright mounting on a horizontal surface.

2. A flippable double-sided desktop easel according to claim 1 and wherein a main portion of said easel is formed in a double-sided mold by injection molding.

3. A flippable double-sided desktop easel according to claim 2 and wherein said mold comprises a base portion and an ejector mold, said base portion comprising a base plate having at least two tracks and an injection mold, corresponding to said ejector mold, mounted thereupon.

4. A flippable double-sided desktop easel according to claim 3 and wherein at least one slidable molding insert element is slidably mounted on said tracks on opposite ends of said injection mold, each of said at least one insert element comprising at least one mold place-holder.

5. A flippable double-sided desktop easel according to claim 4 and wherein slidable movement of said at least one slidable molding insert element relative to said injection mold is controlled by at least one piston which connects between said at least one slidable molding insert element and said injection mold.

6. A flippable double-sided desktop easel according to claim 5 and wherein prior to said injection molding of said main portion, said at least one piston is employed to slidably engage said at least one slidable molding insert element with said injection mold, thereby inserting said at least one mold place-holder into the interior of said injection mold.

7. A flippable double-sided desktop easel according to claim 6 and wherein subsequent to said injection molding of said main portion, said at least one piston is employed to slidably disengage said at least one slidable molding insert element from said injection mold, thereby exposing at least one recess integrally formed in the periphery of said main portion by said mold place-holders.

8. A flippable double-sided desktop easel according to claim 7 and wherein said main portion comprises a first easel panel frame interconnected to a second easel panel frame by integrally formed flexible connectors.

9. A flippable double-sided desktop easel according to claim 8 and wherein at least one of said first and second frames comprises an integrally formed double-sided easel panel.

10. A flippable double-sided desktop easel according to claim 9 and wherein a snap-fit double-sided easel panel is snap fitted into one of said first and second frames.

11. A flippable double-sided desktop easel according to claim 10 and wherein said snap-fit double-sided easel panel comprises electronic drawing functionality.

12. A flippable double-sided desktop easel according to claim 11 and wherein at least one of said first and second frames comprises a compartment having a hinged door, said compartment being operable for storing at least one of electronic components of said electronic drawing functionality and drawing tools.

13. A flippable double-sided desktop easel according to claim 12 and wherein said hinged door is also operative to serve as a tray for placing said drawing tools while using said easel.

14. A flippable double-sided desktop easel according to claim 13 and wherein two top covers are each snap-fitted into a top portion of each of said frames, and leg elements are snap fitted into said at least one recess.

15. A flippable double-sided desktop easel according to claim 14 and wherein adjustable locking elements are provided for interconnecting knobs formed on the periphery of each of said frames, said knobs being operable for locking said frames in one of a generally upright position and a mutually perpendicular arrangement.

16. A flippable double-sided desktop easel according to claim 15 and wherein said top covers, said leg elements and said locking elements are formed by injection molding.

17. A flippable double-sided desktop easel according to claim 16 and wherein each side of said double-sided easel panels comprises at least one of a magnetic board, a chalkboard, a drawing board, and a rub-on coloring board.

18. A flippable double-sided desktop easel according to claim 17 and wherein when in said generally upright position, at least one side of each of said double-sided easel panels is accessible.

19. A flippable double-sided desktop easel according to claim 18 and wherein said interflipping comprises detaching said locking elements from said knobs, flipping one of said frames above and over another one of said frames and reattaching said locking elements to said knobs.

20. A method of manufacturing a flippable double-sided desktop easel comprising:
forming, by injection molding, at least two interconnected double-sided easel panels, said panels being operable for interflipping therebetween, said interflipping being operable to alternatively expose alternating ones of sides of said panels, said interconnected double-sided easel panels being arranged for generally upright mounting on a horizontal surface.

21. A method of manufacturing a flippable double-sided desktop easel according to claim 20 and wherein a main portion of said easel is formed in a double-sided mold.

22. A method of manufacturing a flippable double-sided desktop easel according to claim 21 and wherein said mold comprises a base portion and an ejector mold, said base portion comprising a base plate having at least two tracks and an injection mold, corresponding to said ejector mold, mounted thereupon.

23. A method of manufacturing a flippable double-sided desktop easel according to claim 22 and wherein at least one slidable molding insert element is slidably mounted on said tracks on opposite ends of said injection mold, each of said at least one insert element comprising at least one mold place-holder.

24. A method of manufacturing a flippable double-sided desktop easel according to claim 23 and wherein slidable movement of said at least one slidable molding insert element relative to said injection mold is controlled by at least one piston which connects between said at least one slidable molding insert element and said injection mold.

25. A method of manufacturing a flippable double-sided desktop easel according to claim 24 and also comprising, prior to said injection molding of said main portion, employing said at least one piston to slidably engage said at least one slidable molding insert element with said injection mold, thereby inserting said at least one mold place-holder into the interior of said injection mold.

26. A method of manufacturing a flippable double-sided desktop easel according to claim 25 and also comprising, subsequent to said injection molding of said main portion, employing said at least one piston to slidably disengage said at least one slidable molding insert element from said injection mold, thereby exposing at least one recess integrally formed in the periphery of said main portion by said mold place-holders.

27. A method of manufacturing a flippable double-sided desktop easel according to claim 26 and also comprising integrally forming at least one flexible connector which interconnects between a first easel panel frame of said easel and a second easel panel frame of said easel.

28. A method of manufacturing a flippable double-sided desktop easel according to claim 27 and also comprising integrally forming a double-sided easel panel in at least one of said first and second frames.

29. A method of manufacturing a flippable double-sided desktop easel according to claim 27 and also comprising snap-fitting a snap-fit double-sided easel panel into one of said first and second frames.

30. A method of manufacturing a flippable double-sided desktop easel according to claim 29 and wherein said snap-fit double-sided easel panel comprises electronic drawing functionality.

31. A method of manufacturing a flippable double-sided desktop easel according to claim 30 and also comprising forming, in at least one of said first and second frames, a compartment having a hinged door, said compartment being operable for storing at least one of electronic components of said electronic drawing functionality and drawing tools.

32. A method of manufacturing a flippable double-sided desktop easel according to claim 31 and wherein said hinged door is also operative to serve as a tray for placing said drawing tools while using said easel.

33. A method of manufacturing a flippable double-sided desktop easel according to claim 32 and also comprising snap-fitting two top covers into a top portion of each of said frames, and snap-fitting leg elements into said at least one recess.

34. A method of manufacturing a flippable double-sided desktop easel according to claim 33 and comprising providing adjustable locking elements for interconnecting knobs formed on the periphery of each of said frames, said knobs being operable for locking said frames in one of a generally upright position and a mutually perpendicular arrangement.

35. A method of manufacturing a flippable double-sided desktop easel according to claim 34 and wherein said top covers, said leg elements and said locking elements are formed by injection molding.

36. A method of manufacturing a flippable double-sided desktop easel according to claim 35 and wherein each side of said at least one double-sided easel panel comprises at least one of a magnetic board, a chalkboard, a drawing board, and a rub-on coloring board.

37. A method of manufacturing a flippable double-sided desktop easel according to claim 36 and wherein when in said generally upright position, at least one side of each of said double-sided easel panels is accessible.

38. A method of manufacturing a flippable double-sided desktop easel according to claim 37 and wherein said interflipping comprises detaching said locking elements from said knobs, flipping one of said frames above and over another one of said frames and reattaching said locking elements to said knobs.
